(19) United States
(12) Patent Application Publication
(10) Pub. No.: US 2023/0073259 A1
(43) Pub. Date: Mar. 9, 2023

(54) HIGH TEMPERATURE SUBSTRATE SUPPORT WITH HEAT SPREADER

(71) Applicant: LAM RESEARCH CORPORATION, Fremont, CA (US)

(72) Inventors: Ramesh CHANDRASEKHARAN, Lake Oswego, OR (US); Karl Frederick LEESER, West Linn, OR (US); Christopher GAGE, Truckee, CA (US); Seshu NIMMALA, Beaverton, OR (US); Ramkishan Rao LINGAMPALLI, Danville, CA (US); Joel HOLLINGSWORTH, Portland, OR (US); Vincent BURKHART, Cupertino, CA (US); William LAFFERTY, Oakland, CA (US); Sergey Georgiyevich BELOSTOTSKIY, Sherwood, OR (US)

(21) Appl. No.: 17/799,866

(22) PCT Filed: Feb. 17, 2021
(86) PCT No.: PCT/US2021/018313

§ 371 Date: Aug. 15, 2022

Related U.S. Application Data
(60) Provisional application No. 62/978,119, filed on Feb. 18, 2020.

(51) Int. Cl. H01J 37/32

(52) U.S. Cl. CPC H01J 37/32724; H01J 2237/327

(57) ABSTRACT

A baseplate for a substrate support includes a heater layer configured to selectively heat the baseplate and a heat spreader disposed between the heater layer and an upper surface of the baseplate. The heat spreader is configured to distribute heat provided by the heater layer throughout the baseplate. The baseplate includes a first material that has a first coefficient of thermal expansion (CTE) and a first thermal conductivity. The heat spreader includes a second material that has a second CTE and a second thermal conductivity greater than the first thermal conductivity.

### CROSS-REFERENCE TO RELATED APPLICATIONS

This application claims the benefit of U.S. Provisional Application No. 62/978,119, filed on Feb. 18, 2020. The entire disclosure of the application referenced above is incorporated herein by reference.

### FIELD

The present disclosure relates to maintaining temperature uniformity in substrate supports of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is disposed on a substrate support such as a pedestal or electrostatic chuck including a surface configured to support the substrate. One or more process gases may be introduced into the processing chamber.

The one or more process gases may be delivered by a gas delivery system to the processing chamber. In some systems, the gas delivery system includes a manifold connected by one or more conduits to a showerhead that is located in the processing chamber. In some examples, deposition processes such as chemical vapor deposition (CVD), plasma enhanced CVD (PECVD), atomic layer deposition (ALD), etc. are used to deposit material on a substrate.

### SUMMARY

A baseplate for a substrate support includes a heater layer configured to selectively heat the baseplate and a heat spreader disposed between the heater layer and an upper surface of the baseplate. The heat spreader is configured to distribute heat provided by the heater layer throughout the baseplate. The baseplate includes a first material that has a first coefficient of thermal expansion (CTE) and a first thermal conductivity. The heat spreader includes a second material that has a second CTE and a second thermal conductivity greater than the first thermal conductivity.

In other features, the heater layer includes resistive heating elements. The first material is dielectric. The first material is ceramic. The first material includes at least one of aluminum nitride (AlN), aluminum oxynitride (AlON), and aluminum oxide (Al₂O₃). The second material includes carbon. The second material includes one of pyrolytic graphite, molybdenum-graphite, and diamond. The second CTE is the same as the first CTE. The second CTE is different from the first CTE. The second CTE is greater than the first CTE. The second thermal conductivity is greater than the first thermal conductivity in at least one direction. The second thermal conductivity is greater than the first thermal conductivity in at least an x-y plane.

In other features, the heat spreader includes an inner layer that has the second CTE and an outer layer comprising a third material that has a third CTE that is between the first CTE and the second CTE. The third material includes molybdenum (Mo). The heat spreader includes a middle layer disposed between the inner layer and the outer layer. The middle layer is metallic. The middle layer includes copper.

In other features, the baseplate further includes a plurality of interlayers disposed at least one of between the heat spreader and the upper surface of the baseplate and between the heat spreader and the heater layer. The plurality of interlayers comprises a third material that has a third CTE that is between the first CTE and the second CTE. Individual ones of the plurality of interlayers alternate with layers of the first material. The baseplate further includes a functionally graded material (FGM). The FGM includes the first material and a third material that has a third CTE. The FGM is a functionally graded ceramic (FGC). The baseplate further includes a cap layer disposed on the heat spreader. The cap layer includes the first material.

In other features, a substrate support includes the baseplate and further includes a skirt ring assembly surrounding the baseplate. The heat spreader is isotropic. The heat spreader has at least one of anisotropic thermal conductivity and an anisotropic CTE.

A substrate support for a substrate processing system includes a baseplate comprising a functionally graded material (FGM). The FGM includes a dielectric material and a graded filler material. A heat spreader is embedded within the baseplate. The heat spreader is configured to distribute heat throughout the baseplate and the heat spreader has a first coefficient of thermal expansion (CTE) and a first thermal conductivity. The FGM has a second CTE and a second thermal conductivity.

In other features, the first CTE is the same as the second CTE. The first CTE is different from the second CTE. The FGM is a functionally graded ceramic (FGC). The FGC is a ceramic matrix composite (CMC) material. The second CTE of the FGM varies in a vertical direction.

A substrate support for a substrate processing system includes a baseplate. The baseplate includes a first material that has a first coefficient of thermal expansion (CTE) and a first thermal conductivity. A heater layer is embedded within the baseplate and a heat spreader is disposed on the baseplate. The heat spreader is configured to spread heat generated by the heater layer in a lateral direction. The heat spreader includes a second material that has a second CTE and a second thermal conductivity greater than the first thermal conductivity. A cap layer is disposed on the heat spreader.

In other features, the cap layer includes the first material. The cap layer includes the second material. The cap layer includes a third material. A skirt ring assembly surrounds the baseplate. The first CTE is the same as the second CTE. The first CTE is different from the second CTE.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2 is an example substrate support including a heat spreader according to the present disclosure;

FIG. 3 is another example substrate support including a heat spreader according to the present disclosure;

FIG. 4 is another example substrate support including a heat spreader according to the present disclosure;

FIG. 5 is another example substrate support including a heat spreader according to the present disclosure; and

FIGS. 6A and 6B show example heat spreaders according to the present disclosure.

In the drawings, reference numbers may be reused to identify similar and/or identical elements.

### DETAILED DESCRIPTION

In film deposition processes such as atomic layer deposition (ALD), various properties of the deposited film vary across a spatial (i.e., x-y coordinates of a horizontal plane) distribution. For example, substrate processing tools may have respective specifications for film thickness non-uniformity (NU). Film thickness NU may be measured as a full-range, a half-range, a standard deviation, etc. of a measurement set taken at predetermined locations on a surface of a semiconductor substrate. In some examples, the NU may be reduced by addressing a direct cause of the NU. In other examples, the NU may be reduced by introducing a counteracting NU to compensate and cancel the existing NU. In other examples, material may be intentionally deposited and/or removed non-uniformly to compensate for known non-uniformities at other (e.g. previous or subsequent) steps in a process.

Deposition rates may be partially dependent upon substrate temperatures. Accordingly, temperature NUs (i.e., differences in temperatures across the substrate) may cause different deposition rates and corresponding film thickness NUs. A substrate processing system may implement various temperature control schemes to control the temperatures of the substrate to minimize NUs. For example, a substrate support (i.e., a structure with a generally flat upper surface configured to support a substrate during processing, such as a pedestal) may include a heater layer. The heater layer may include one or more zones that are respectively controlled to maintain desired temperatures of the substrate support and, correspondingly, the substrate.

In some examples, the heater layer includes resistive heating elements or heaters. Typically, the heater layer is embedded within the substrate support (e.g., a pedestal) comprised of a dielectric material having high thermal conductivity, such as ceramic (e.g., aluminum nitride (AlN)). Some ceramic materials, including AlN, experience a decrease in thermal conductivity at higher temperatures (e.g., above 500 degrees Celsius). Differences in thermal conductivity across the substrate support may cause asymmetric thermal NUs that affect deposition. More specifically, heat provided by the heater layer may not be sufficiently distributed throughout the substrate support to provide temperature uniformity. Further, materials such as AlN may limit temperatures and chemistries that may be used in some processes (e.g., cleaning processes).

Systems and methods according to the principles of the present disclosure implement a heat spreader (e.g., a layer comprising or encapsulated in a thermally conductive material) bonded to and/or embedded within a substrate support. The heat spreader is configured to uniformly distribute (e.g., in a horizontal direction) heat from the heater layer throughout the substrate support. The heat spreader has a greater thermal conductivity than the material (e.g., AlN) of the substrate support (e.g., a baseplate of the substrate support). The heat spreader may be comprised of a material including, but not limited to, pyrolytic graphite bonded to or embedded/contained within AlN, moly-graphite composite bonded to or embedded/contained within AlN, diamond (e.g., CVD diamond), etc. In some examples, the substrate support is comprised of a material other than AlN, including, but not limited to, aluminum oxynitride (AlON), Al₂O₃, mixtures thereof, etc. The material may include secondary stabilizers such as TiOₓ, Y₂Oₓ, La₂Oₓ, etc.

The heat spreader may be a continuous heat spreader layer. The heat spreader may have a specific shape or geometry to provide a desired temperature distribution pattern. For example, the heat spreader may comprise one or more rings, azimuthal rings, columnar structures, etc. In some examples, the heat spreader comprises a layer such as a plate that is mechanically attached to adjacent layers of the substrate support. In other examples, the heat spreader may comprise a powder or other material (e.g., indium) that is embedded or otherwise used to fill cavities or channels within the substrate support subsequent to manufacture.

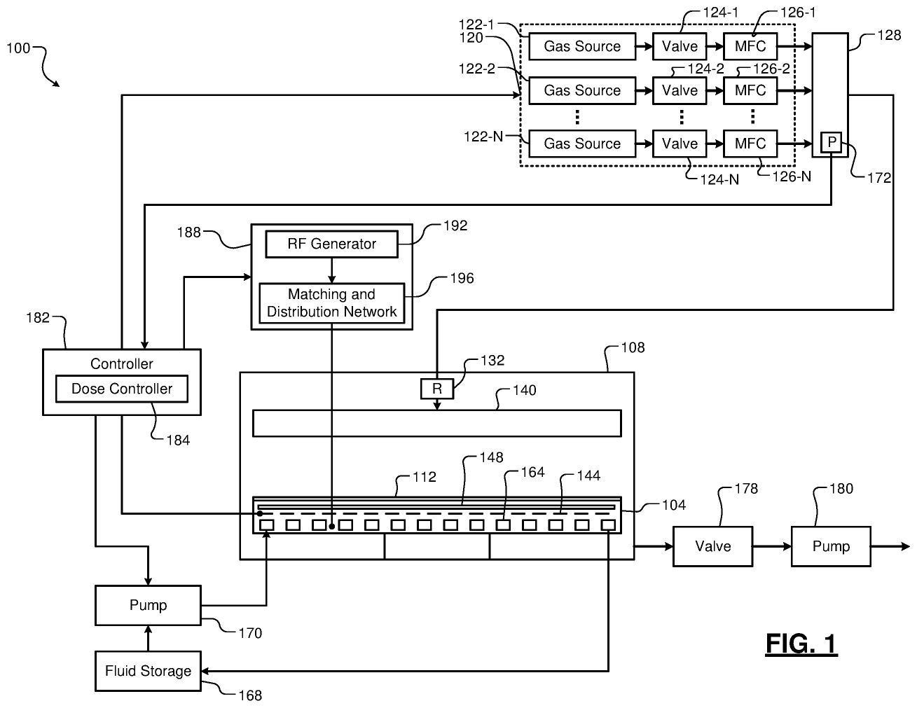

Referring now to FIG. 1, an example of a substrate processing system 100 including a substrate support (e.g., an ALD pedestal) 104 according to the present disclosure is shown. The substrate support 104 is disposed within a processing chamber 108. A substrate 112 is disposed on the substrate support 104 during processing.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a gas distribution device such as a multi-injector showerhead 140.

A temperature of the substrate support 104 may be controlled using a heater layer, such as resistive heaters 144. The substrate support 104 according to the principles of the present disclosure includes a heat spreader 148 as described below in more detail. The substrate support 104 may include coolant channels 164. Cooling fluid is supplied to the coolant channels 164 from a fluid storage 168 and a pump 170. A pressure sensor 172 may be disposed in the manifold 128 to measure pressure. A valve 178 and a pump 180 may be used to evacuate reactants from the processing chamber 108. The valve 178 and the pump 180 may be used to control pressure within the processing chamber 108.

A controller 182 includes a dose controller 184 that controls dosing provided by the multi-injector showerhead 140. The controller 182 also controls gas delivery from the gas delivery system 120. The controller 182 controls pressure in the processing chamber and/or evacuation of reactants using the valve 178 and the pump 180. The controller 182 controls the temperature of the substrate support 104 and the substrate 112 based upon temperature feedback. For example, the temperature feedback may correspond to feedback from sensors (not shown) in the substrate support, sensors (not shown) measuring coolant temperature, etc.

In some examples, the substrate processing system 100 may be configured to perform etching on the substrate 112 within the same processing chamber 108. For example, the substrate processing system 100 may be configured to perform both a trim step and a spacer deposition step according to the present disclosure as described below in more detail. Accordingly, the substrate processing system 100 may include an RF generating system 188 configured to generate and provide RF power (e.g., as a voltage source, current source, etc.) to a lower electrode (e.g., a baseplate of the substrate support 104, as shown) and an upper electrode (e.g., the showerhead 140). For example purposes only, the output of the RF generating system 188 will be described herein as an RF voltage. The lower electrode and the upper electrode may be DC grounded, AC grounded or floating. For example, the RF generating system 188 may include an RF generator 192 configured to generate the RF voltage that is fed by a matching and distribution network 196 to generate plasma within the processing chamber 108 to etch the substrate 112. In other examples, the plasma may be generated inductively or remotely. Although, as shown for example purposes, the RF generating system 188 corresponds to a capacitively coupled plasma (CCP) system, the principles of the present disclosure may also be implemented in other suitable systems. For example, the principles of the present disclosure may be implemented in transformer coupled plasma (TCP) systems, CCP cathode systems, remote microwave plasma generation and delivery systems, etc.

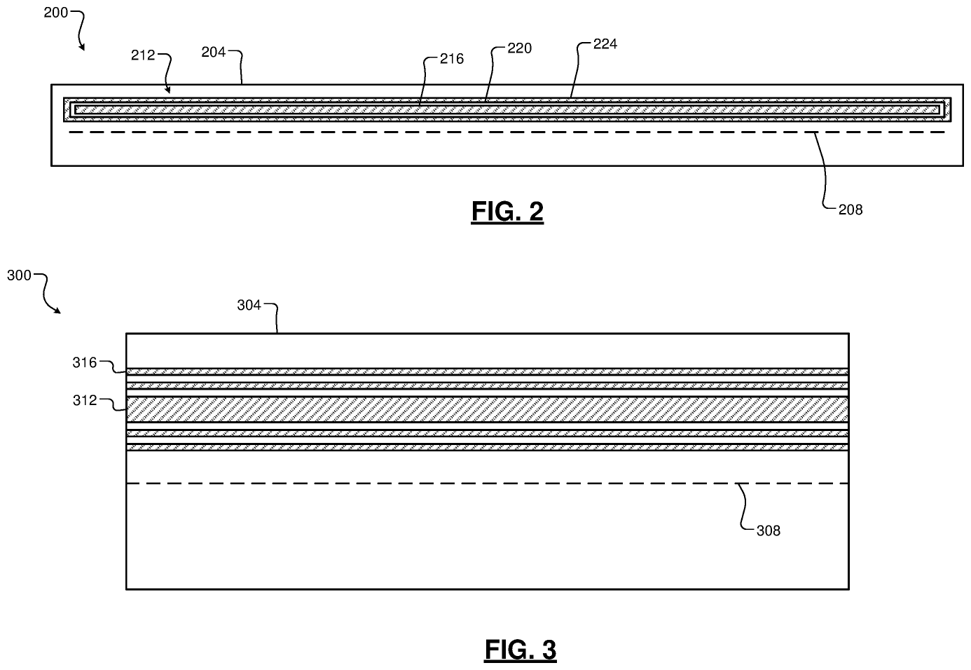

Referring now to FIG. 2, an example substrate support 200 according to the present disclosure includes a baseplate 204 with a heater layer 208 and an embedded heat spreader 212. For example, the baseplate 204 is comprised of a dielectric material including, but not limited to, AlN or Al₂O₃. In some examples, the baseplate 204 may include boron nitride. In some examples, the baseplate 204 is coated in a fluorine (F) and oxygen resistant material (e.g., zirconia (ZrO₂)). The heat spreader 212 includes an inner (e.g., encapsulated) layer 216 comprising a thermally conductive material (e.g., carbon, such as pyrolytic graphite, diamond, or molybdenum-graphite, boron nitride (h-BN or BN), etc.). For example, the heat spreader 212 may have a thermal conductivity between 100 and 1500 watts per meter Kelvin (W/m-k) at temperatures between 500 and 700 degrees Celsius. The inner layer 216 is configured to laterally (i.e., horizontally) distribute heat generated by the heater layer 208 throughout the baseplate 204. For example, the inner layer 216 has greater thermal conductivity than the material of the baseplate 204.

The material of the inner layer 216 may have various physical and/or chemical incompatibilities with respect to the material of the baseplate 204. For example, the inner layer 216 and the baseplate 204 may have different coefficients of thermal expansion (CTEs). In some examples, the inner layer 216 and the baseplate may have the same CTE. Accordingly, the inner layer 216 may be encapsulated in one or more additional layers to provide a stable physical interface between the inner layer 216 and the baseplate 204. For example, the heat spreader 212 may include a middle layer 220 comprised of a metallic material such as copper (Cu) surrounding the inner layer 216. An outer layer 224 surrounds the middle layer 220. For example only, the outer layer 224 is comprised of molybdenum (Mo).

The outer layer 224 may have a CTE nearer to the CTE of the baseplate 204 than to the inner layer 216. Accordingly, the inner layer 216 may have similar incompatibilities with the outer layer 224. The middle layer 220 provides an interface between the inner layer 216 and the outer layer 224. In an example, the inner layer 216 may have a first CTE that is greater than (or less than) a second CTE of the baseplate 204. The middle layer 220 and/or the outer layer 224 (individually or in combination) may have a third CTE that is between the first CTE and the second CTE. In this manner, the heat spreader 212 provides a transition of CTEs of the respective materials of the inner layer 216, the middle layer 220, and the outer layer 224 to more closely match the CTE of the baseplate 204. Other suitable materials may be substituted for the inner layer 216, the middle layer 220, and/or the outer layer 224. The materials may include composite materials, materials with graded chemistry and/or graded fillers, and alloys such as low CTE ferrous and nickel alloys.

In some examples, the heat spreader 212 has isotropic properties. In other examples, the heat spreader 212 has anisotropic properties, such as anisotropic thermal conductivity and/or anisotropic CTE. For example, the heat spreader 212 may have greater thermal conductivity in a horizontal direction than in a vertical direction to improve temperature uniformity in the substrate support 200 in the horizontal direction. In other examples, the heat spreader 212 may have greater thermal conductivity in the vertical direction than in the horizontal direction to maximize distribution of heat from the heater layer 208 to the upper surface of the baseplate 204 while limiting distribution of heat between different radial or azimuthal zones of the baseplate 204. In still other examples, the heat spreader 212 may have a greater CTE in the vertical or horizontal direction.

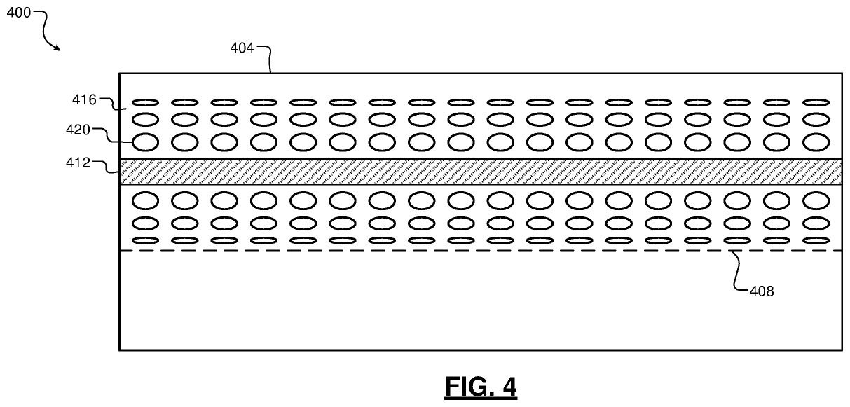

In some examples, the heat spreader may be implemented as one or more materials that provide CTE gradation to provide uniform temperature distribution for high-temperature processes. The materials also provide CTE matching to minimize decoupling and delamination between layers of the heat spreader and a surrounding material. For example, heat spreader layers and/or the surrounding material may be implemented as a ceramic matrix composite (CMC) including a filler (e.g., spinel), a functionally graded material (FGM), etc. FIG. 3 shows a section of another example substrate support 300. The substrate support 300 includes a baseplate 304 with a heater layer 308 and an embedded heat spreader 312. For example, the baseplate 304 is comprised of a dielectric material including, but not limited to, AlN or Al₂O₃. In this example, the baseplate 304 includes one or more interlayers 316 that provide a transitional interface between the heat spreader 312 and the material of the baseplate 304.

For example, the heat spreader 312 may have a first CTE that is greater than (or less than) a second CTE of the material of the baseplate 304. Conversely, the material of the interlayers 316 may have a third CTE that is between the first CTE and the second CTE. The material of the baseplate 304 may be disposed in layers between the interlayers 316 and between the interlayers 316 and the heat spreader 312.

Referring now to FIG. 4, a section of another example substrate support 400 includes a baseplate 404 comprising an FGM such as functionally graded ceramic (FGC). The baseplate includes a heater layer 408 and an embedded heat spreader 412. For example, the baseplate 404 implements the FGC as a CMC including dielectric material (e.g., a ceramic such as AlN or Al₂O₃) 416 and a graded filler 420 (e.g., boron nitride (h-BN)). For example only, the dielectric material 416 and/or the filler 420 may be formed using powder metallurgy sheet lamination, CVD, sintering, and/or other fabrication or coating processes. FGMs have one or more physical properties (e.g., CTE) that change in accordance with dimensions (e.g., vertical distance). The physical properties may change based on changes in one or more characteristics of the filler 420, including, but not limited to, a fraction (amount relative to the dielectric material 416), shape, orientation, particle size, etc.

For example, the heat spreader 412 may have a first CTE that is greater than (or less than) a second CTE dielectric material 416 of the baseplate 404. The filler 420 has a third CTE that is between the first CTE and the second CTE. Accordingly, changes in characteristics of the filler 420 relative to the dielectric material 416 changes an overall CTE of the baseplate 404 in a given vertical region or zone. In other words, the overall CTE of the baseplate 404 may be nearer to the first CTE of the heat spreader 412 in a region adjacent to the heat spreader 412. Conversely, as a distance from the heat spreader 412 increases, the CTE of the baseplate 404 decreases (or increases). A gradient of the CTE of the baseplate 404 may be linear, exponential, step-wise, etc. In this manner, the graded filler 420 provides CTE matching and reduces thermal stress caused by CTE mismatches between the heat spreader 412 and the dielectric material 416.

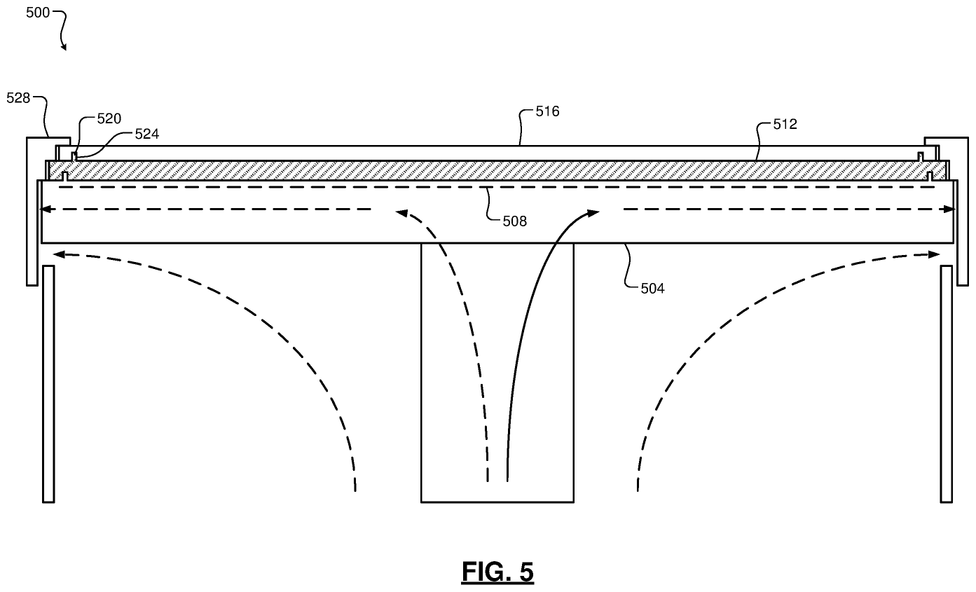

Referring now to FIG. 5, another example substrate support 500 includes a baseplate 504 with an embedded heater layer 508. A heat spreader 512 is disposed on the baseplate 504. A cap layer 516 is disposed on the heat spreader 512. The cap layer 516 may have a thickness between 1.0 and 3.0 mm. For example, the baseplate 504 and the cap layer 516 are comprised of a dielectric material (e.g., ceramic) including, but not limited to, AlN or Al₂O₃. The baseplate 504 and the cap layer 516 may comprise the same or different materials. The heat spreader 512 comprises a thermally conductive material (e.g., carbon, such as pyrolytic graphite, diamond, etc.). that is configured to laterally (i.e., horizontally) distribute heat generated by the heater layer 508 throughout the cap layer 516. In some examples, the heat spreader 512 is electrically conductive and may therefore function as a lower electrode.

The cap layer 516 may be removable and replaceable. For example, the cap layer 516 may be exposed to process materials while protecting the heat spreader 512 and the baseplate 504 from exposure to process materials. Accordingly, the cap layer 516 may be a consumable part that is periodically replaced. The heat spreader 512 may also be replaceable. The cap layer 516 and the heat spreader 512 may be configured based on desired performance characteristics. For example, different ones of the cap layer 516 and/or the heat spreader 512 may be selectively installed based on desired CTE values for specific processes, substrate types, etc. In some examples, the baseplate 504, the heat spreader 508, and/or the cap layer 516 may be aligned using respective pairs of slots 520 and alignment features 524. For example, the slots 520 may be provided in respective lower surfaces of the cap layer 516 and/or the heat spreader 512. Conversely, the alignment features 524 may extend upward from respective upper surfaces of the heat spreader 512 and the baseplate 504.

The heat spreader 512 is not fixedly attached (e.g., bonded with adhesive) to the baseplate 504 and the cap layer 516. Accordingly, differences between respective CTEs of the heat spreader 512, the baseplate 504, and the cap layer 516 do not cause thermal stress and corresponding mechanical failures of the substrate support 500.

A skirt ring assembly 528 may surround the substrate support 500. The skirt ring assembly 528 protects surfaces of the baseplate 504 and the heat spreader 512 from erosion caused by process materials, reduces parasitic plasma, reduces plasma light-up, etc. In some examples, purge gas may be provided in a volume below the baseplate 504 and/or upward through a stem 532 and into gaps between the skirt ring assembly 528 and the substrate support 500. The purge gas prevents process materials from leaking from a processing volume into the gaps. Accordingly, surfaces of the baseplate 504 and the heat spreader 512 are further protected from process materials and parasitic plasma. Further, plasma light-up in the gaps and on a backside of the baseplate 504 is reduced.

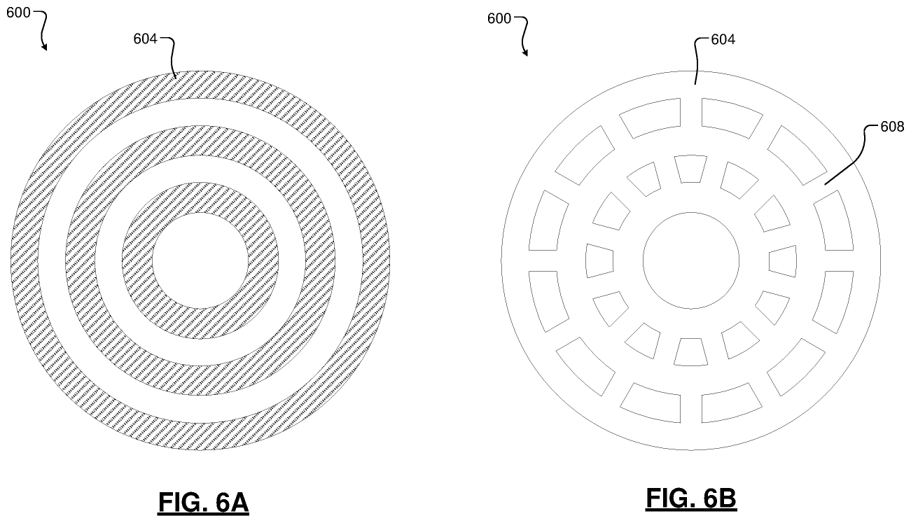

In some examples, the heat spreader may be a continuous heat spreader layer. The heat spreader may have a specific shape or geometry to provide a desired temperature distribution pattern. As shown in FIGS. 6A and 6B, an example heat spreader 600 may comprise one or more rings 604. The rings 604 may be comprised of same or different materials. For example, the rings 604 may respectively be comprised of materials having desired CTEs for particular zones of a substrate support. As shown in FIG. 6B, the heat spreader 600 further includes radial spokes 608 connecting the rings 604 together. In this manner, the heat spreader 600 may be configured to compensate for specific zone-based (e.g., radial or azimuthal) NUs.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A baseplate for a substrate support, the baseplate comprising:
a heater layer configured to selectively heat the baseplate; and
a heat spreader disposed between the heater layer and an upper surface of the baseplate, wherein the heat spreader is configured to distribute heat provided by the heater layer throughout the baseplate, and wherein
the baseplate comprises a first material that has a first coefficient of thermal expansion (CTE) and a first thermal conductivity, and
the heat spreader comprises a second material that has a second CTE different from the first CTE and a second thermal conductivity greater than the first thermal conductivity.

2. The baseplate of claim 1, wherein the heater layer comprises resistive heating elements.

3. The baseplate of claim 1, wherein the first material is dielectric.

4. The baseplate of claim 1, wherein the second material comprises at least one of carbon, pyrolytic graphite, molybdenum-graphite, and diamond.

5. The baseplate of claim 1, wherein the second CTE is different from the first CTE.

6. The baseplate of claim 1, wherein the second CTE is greater than the first CTE.

7. The baseplate of claim 1, wherein the heat spreader comprises an inner layer that has the second CTE and an outer layer comprising a third material that has a third CTE that is between the first CTE and the second CTE.

8. The baseplate of claim 7, wherein the heat spreader comprises a middle layer disposed between the inner layer and the outer layer.

9. The baseplate of claim 1, further comprising a plurality of interlayers disposed at least one of (i) between the heat spreader and the upper surface of the baseplate and (ii) between the heat spreader and the heater layer.

10. The baseplate of claim 9, wherein the plurality of interlayers comprises a third material that has a third CTE that is between the first CTE and the second CTE.

11. The baseplate of claim 9, wherein individual ones of the plurality of interlayers alternate with layers of the first material.

12. The baseplate of claim 1, wherein the heat spreader is isotropic.

13. The baseplate of claim 1, wherein the heat spreader has at least one of anisotropic thermal conductivity and an anisotropic CTE.

14. The baseplate of claim 1, wherein the baseplate further comprises a functionally graded material (FGM).

15. A substrate support for a substrate processing system, the substrate support comprising:
a baseplate comprising a functionally graded material (FGM), wherein the FGM comprises a dielectric material and a graded filler material; and
a heat spreader embedded within the baseplate, wherein the heat spreader is configured to distribute heat throughout the baseplate, and wherein the heat spreader has a first coefficient of thermal expansion (CTE) and a first thermal conductivity,
wherein the FGM has a second CTE and a second thermal conductivity.

16. The substrate support of claim 15, wherein the FGM is a functionally graded ceramic (FGC).

17. The substrate support of claim 16, wherein the FGC is a ceramic matrix composite (CMC) material.

18. The substrate support of claim 15, wherein the second CTE of the FGM varies in a vertical direction.

19. The substrate support of claim 16, wherein the first CTE is different from the second CTE.

20. A substrate support for a substrate processing system, the substrate support comprising:
a baseplate that comprises a first material that has a first coefficient of thermal expansion (CTE) and a first thermal conductivity;
a heater layer embedded within the baseplate;
a heat spreader disposed on the baseplate, wherein the heat spreader is configured to spread heat generated by the heater layer in a lateral direction, and wherein the heat spreader comprises a second material that has a second CTE and a second thermal conductivity greater than the first thermal conductivity; and
a cap layer disposed on the heat spreader.
